(19) United States
(12) Patent Application Publication
(10) Pub. No.: US 2002/0109105 A1
(43) Pub. Date: Aug. 15, 2002

(54) Method of ion implantation

(76) Inventors: Chien-Chih Lin, Hsinchu Hsien (TW); Michael WC Huang, Taipei Hsien (TW); Tien-Chang Chang, Taiepi Hsien (TW)

Correspondence Address: CHARLES C.H. WU & ASSOCIATES, Suite 710, 7700 IRVINE CENTER DRIVE, Irvine, CA, 92618-3043, US

(21) Appl. No.: 09/782,424

(22) Filed: Feb. 13, 2001

(51) Int. Cl. G21K 5/10; H01J 37/08

(52) U.S. Cl. 250/492.21

(57) ABSTRACT

The invention provides a method of ion implantation, comprising forming a shield layer over a provided substrate. After forming the shield layer, a photoresist layer is formed over the substrate and then patterned by photolithography and etching. Using the patterned photoresist layer as a mask, an ion implantation step is performed with a tilt angle of zero degree. Next, the shield layer can be removed simultaneously during the process of removing the photoresist layer.

### BACKGROUND OF THE INVENTION

1. Field of Invention

The present invention relates to a process for doping ions. More particularly, the present invention relates to a method of ion implantation.

2. Description of Related Art

Ion implantation is one of the most conventional techniques for doping ions in semiconductor manufacture processes. For semiconductor devices, the common solid target substrate for ion implantation is normally silicon with a specific lattice structure. The crystalline material consists of atoms arranged in a three-dimensional periodic fashion. Therefore, if the direction of ion implantation is parallel to the main crystalline orientation, i.e. in a direction in which the silicon atoms do not hinder the ion implantation, the implanted ions will be doped into the silicon substrate deeply than expected. That is, because of the silicon lattice structure, there are some long, deep, channel-like openings in the substrate, and the implanted ions will be channeled, or steered, along such open channels, if the direction of ion implantation is parallel to these channel-like openings. This is called the channeling effect.

The channeling effect causes difficulty in controlling the depth of implanted ions, especially in ULSI devices. The junction depth of the MOS device is normally 2000 to 4000 angstroms. Thus, any channeling effect can result in the ions implanted deeper than expected, thereby reducing performance of the device.

In order to avoid degrading of the device caused by the channeling effect, one way is to tilt the wafer with a slight tilt angle toward the direction of the implanted ions. Normally the tilt angle is about 7 degrees.

FIG. 1 is a top view of a semiconductor device before ion implantation according to the prior art.

As shown in FIG. 1, a provided silicon substrate 100 contains a region 102 that is designated to form a polysilicon gate in the following process. The substrate further includes isolation structures 104 (shown in FIG. 2) to define an active region 106.

FIG. 2 shows a sectional side view of FIG. 1 according to the II-II section. As shown in FIG. 2, a patterned photoresist layer 108 is formed over the substrate 100 by forming a photoresist layer first and then applying a photolithography process to the photoresist layer. Using the patterned photoresist layer 108 as a mask, an ion implantation step 110 is performed to form a diffusion region 114.

In the ion implantation step 110, a tilt angle of about 7 degrees is used in order to prevent the channeling effect. However, margins 112 of the isolation structures 104 may be shielded by the patterned photoresist layer 108 and thus not be doped during ion implantation because of this tilt angle. This is called the shadowing effect.

FIG. 3 is a top view of the semiconductor device shown in FIG. 2 after ion implantation. After the ion implantation step 110, undoped or partially doped regions 116 are formed on both sides of the active region 106 due to the tilt angle. Therefore, doping concentration in the diffusion region 114 is not uniform, further causing threshold voltage roll-off.

FIG. 4 is a display view illustrating an ion implantation step for forming a well region in a semiconductor device according to the prior art.

Referring to FIG. 4, normally, a tilt angle of 7 degrees is used as the ion implantation angle for a well ion implantation step 410, thus forming a diffusion region 414 in a substrate 400. As dimensions of the device decrease, it causes more difficulties for the ion implantation step. For example, during the well ion implantation step 410, ions can not be doped into edges 412 of the diffusion region 414 because of hindrance from the patterned photoresist 408. The deficiency of ion implantation in the edges 412, especially the edges 412 beside isolation structures 404, can cause so-called inter-well isolation failure.

According to the prior art, the devices formed with tilt angled ion implantation have disadvantages, including non-uniform dopant concentration due to the shadowing effect and dopant profile shifting from the predetermined position.

### SUMMARY OF THE INVENTION

The present invention provides a method of ion implantation for solving problems caused by the shadowing effect.

As embodied and broadly described herein, the invention provides a method of ion implantation, comprising forming a shield layer over a provided substrate. After forming the shield layer, a photoresist layer is formed over the substrate and then patterned by photolithography and etching. Using the patterned photoresist layer as a mask, an ion implantation step is performed with a tilt angle of zero degree. Next, the shield layer can be removed simultaneously during the process of removing the photoresist layer.

In the present invention, the shield layer over the substrate is used to prevent damage from the channeling effect. Furthermore, a tilt angle of zero degree is applied to avoid the shadowing effect. The method provided by the present invention is useful, especially for devices with small dimensions. As dimensions of the device decrease, the difference between the thickness of the photoresist layer and the dimension of the device becomes more significant, thus causing the shadowing effect with even small tilt angles. In addition to preventing damage from the channeling effect, the material of the shield layer is chosen for its ability to be removed together with the photoresist layer during the process of removing the photoresist layer.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIG. 1 is a top view of the semiconductor device before ion implantation according to the prior art;

FIG. 2 shows a sectional view of FIG. 1 according to the II-II section;

FIG. 3 is a top view of the semiconductor device shown in FIG. 2 after ion implantation;

FIG. 4 is a display view illustrating an ion implantation step for forming a well region in a semiconductor device according to the prior art;

FIG. 5A to FIG. 5D are cross-sectional views for illustrating the process steps of an ion implantation method in a semiconductor device according to one preferred embodiment of the present invention; and

FIG. 6A to FIG. 6B are cross-sectional views for illustrating the process steps of an ion implantation method in a semiconductor device according to another preferred embodiment of the present invention.

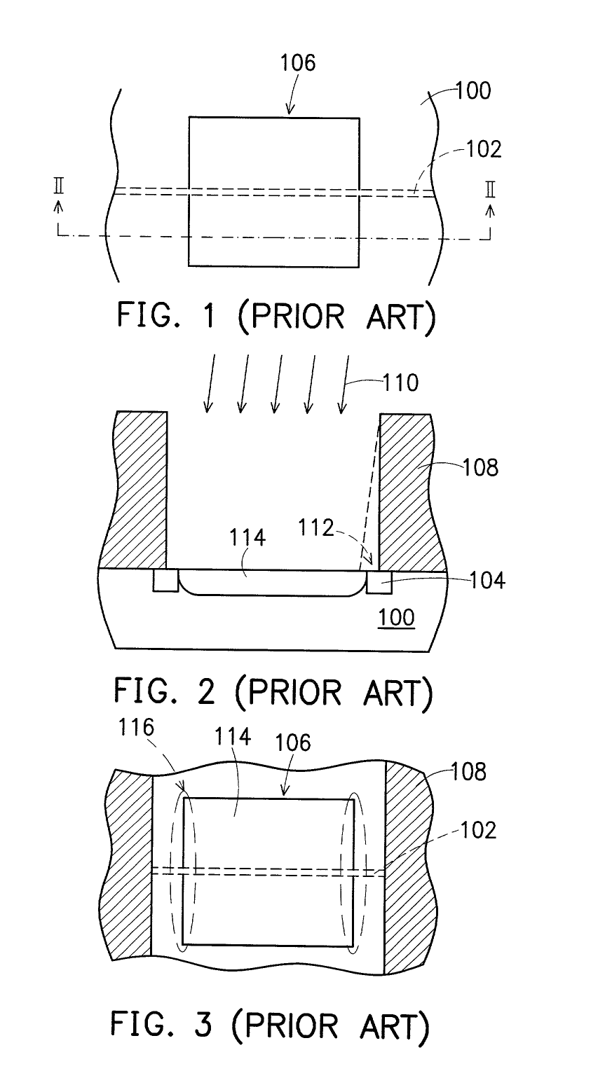

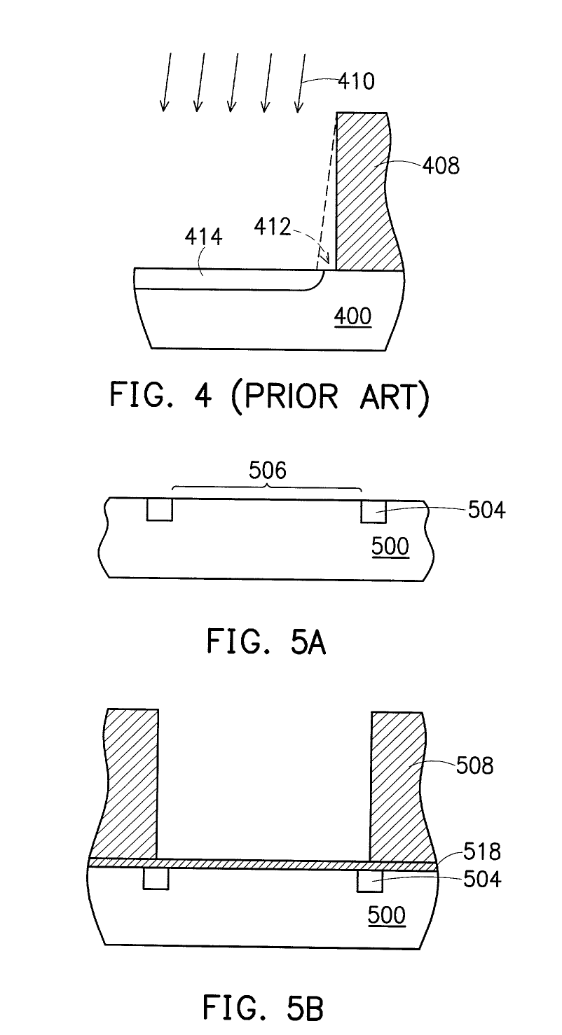

### DESCRIPTION OF THE PREFERRED EMBODIMENTS

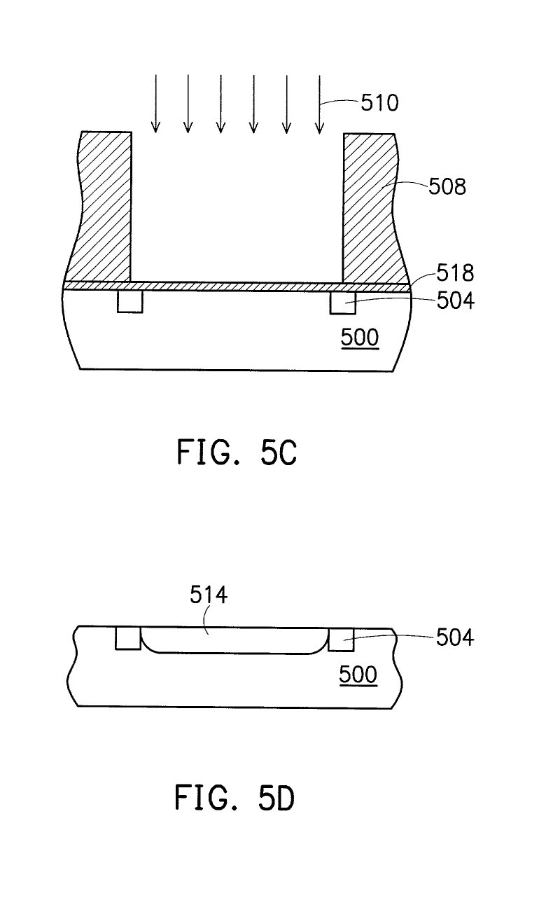

FIG. 5A to FIG. 5D are cross-sectional views for illustrating process steps of an ion implantation method in a semiconductor device according to one preferred embodiment of the present invention.

Referring to FIG. 5A, a substrate 500 is provided with a gate (not shown) and isolation structures 504. An active region 506 is defined by the isolation structures 504.

Referring now to FIG. 5B, a shield layer 518 is formed over the substrate 500. The shield layer 518 can be, for example, a bottom anti-reflection coating (BARC) layer. Preferably, the shield layer 518 can be an organic bottom anti-reflection coating layer with a thickness of about 600-900 angstroms. The shield layer 518 can be removed simultaneously during the following process of removing a photoresist layer.

After forming the shield layer 518, a photoresist layer 508 is formed over the substrate 500 and then patterned by photolithography and etching. The photoresist layer 508 has a thickness, for example, of about 2.5 microns.

Referring to FIG. 5C, using the patterned photoresist layer 508 as a mask, an ion implantation step 510 is performed with a tilt angle of zero degree to form a diffusion region 514 in the substrate 500. Because of the zero tilt angle, no shadowing effect occurs, thus preventing non-uniform implantation concentration in specific regions of the device.

Referring to FIG. 5D, the photoresist layer 508 and the shield layer 518 are removed simultaneously. Because the material of the shield layer 518 is chosen to be removable together with the photoresist layer 508 during the process of removing the photoresist layer 508, no extra step is required to remove the shield layer 518.

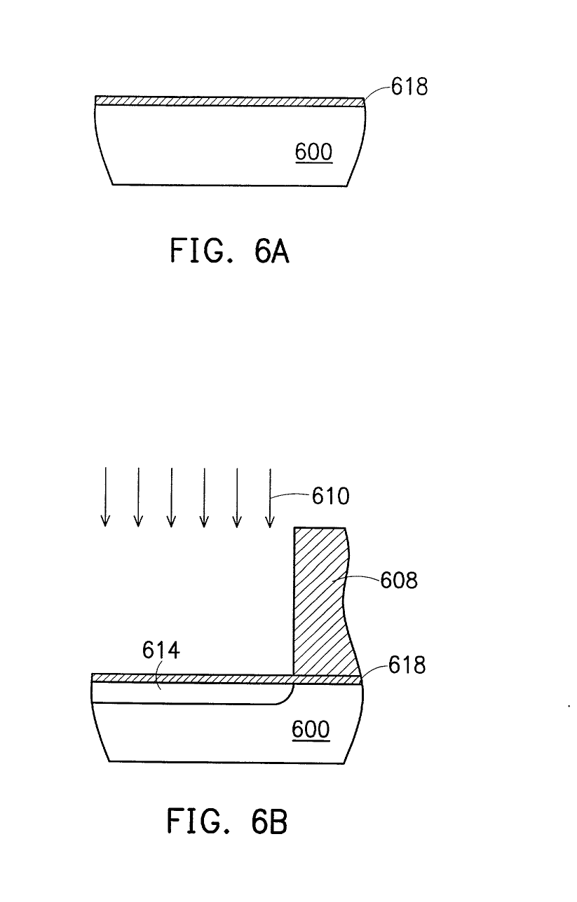

FIG. 6A to FIG. 6B are cross-sectional views for illustrating process steps of an ion implantation method in a semiconductor device according to another preferred embodiment of the present invention.

Referring to FIG. 6A, a shield layer 618 is formed over a substrate 600. The shield layer 618 can be, for example, a bottom anti-reflection coating (BARC) layer. Preferably, the shield layer 618 can be an organic bottom anti-reflection coating layer with a thickness of about 600-900 angstroms. The shield layer 618 can be removed simultaneously during the following process of removing a photoresist layer.

Referring to FIG. 6B, after forming the shield layer 618, a photoresist layer 608 is formed over the substrate 600 and then patterned by photolithography and etching. The photoresist layer 608 has a thickness, for example, of about 2.5 microns. Next, using the patterned photoresist layer 608 as a mask, an ion implantation step 610 is performed with a tilt angle of zero degree to form a diffusion region 614 in the substrate 600. Because of the zero tilt angle, no shadowing effect occurs, thus preventing non-uniform implantation concentration in specific regions of the device and avoiding the inter-well isolation failure.

Accordingly, the advantages of the present invention include the following:

(1) In the present invention, a tilt angle of zero degree is applied, thus avoiding the shadowing effect. The method provided by the present invention is useful, especially for devices with small dimensions. As dimensions of the device decrease, the difference between the thickness of the photoresist layer and the dimension of the device becomes more significant, causing the shadowing effect with even small tilt angles.

(2) The shield layer is formed over the substrate before forming the photoresist layer, thus preventing damage from the channeling effect caused by using a zero tilt angle.

(3) In addition to preventing damage from the channeling effect, the material of the shield layer is chosen for its ability to be removed together with the photoresist layer during the process of removing the photoresist layer. Thus no extra step is required for removing the shield layer.

(4) The zero tilt angle for the ion implantation is applied to avoid the shadowing effect, so that edges of the active region beside the photoresist layer will not have the prior art problems of non-uniform dopant concentration in the source/drain region.

(5) Because a tilt angle of zero degree is used for ion implantation to form a well region, the shadowing effect can be prevented, thus avoiding the inter-well isolation failure, even as the dimensions of the device shrink.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A method of ion implantation, comprising:
providing a substrate with at least an isolation structure for defining an active region;
forming a shield layer over the substrate;
forming a photoresist layer over the substrate and patterning the photoresist layer by photolithography, so that the active region is exposed;
using the patterned photoresist layer as a mask to implant ions into the substrate with a tilt angle of zero degree; and
removing the photoresist layer and the shield layer simultaneously.

2. The method as claimed in claim 1, wherein the shield layer has a thickness of about 600 to 900 angstroms.

3. The method as claimed in claim 1, wherein the shield layer comprises a bottom anti-reflection coating layer.

4. The method as claimed in claim 1, wherein the shield layer comprises an organic bottom anti-reflection coating layer.

5. The method as claimed in claim 1, wherein the photoresist layer has a thickness of about 2.5 microns.

6. A method of ion implantation, comprising:
providing a substrate;
forming a shield layer over the substrate;
forming a photoresist layer over the substrate;
patterning the photoresist layer, so that a first region of the substrate is exposed;
using the patterned photoresist layer as a mask to implant ions into the first region in the substrate with a tilt angle of zero degree, so that a diffusion region is formed; and
removing the photoresist layer and the shield layer simultaneously.

7. The method as claimed in claim 6, wherein the diffusion is a well region.

8. The method as claimed in claim 6, wherein the diffusion is an active region.

9. The method as claimed in claim 6, wherein the shield layer has a thickness of about 600 to 900 angstroms.

10. The method as claimed in claim 6, wherein a material of the shield layer is chosen to be removable along with the photoresist layer.

11. The method as claimed in claim 6, wherein the shield layer comprises a bottom anti-reflection coating layer.

12. The method as claimed in claim 6, wherein the shield layer comprises an organic bottom anti-reflection coating layer.

13. The method as claimed in claim 6, wherein the photoresist layer has a thickness of about 2.5 microns.
